(19) United States
(12) Patent Application Publication
(10) Pub. No.: US 2009/0098907 A1
(43) Pub. Date: Apr. 16, 2009

(54) Parked Vehicle Location Information Access via a Portable Cellular Communication Device

(75) Inventors: Fred W. Huntzicker, Ann Arbor, MI (US); Clark E. McCall, Ann Arbor, MI (US)

Correspondence Address: GENERAL MOTORS CORPORATION;LEGAL STAFF, MAIL CODE 482-C23-B21, P O BOX 300, DETROIT, MI, 48265-3000, US

(73) Assignee: GM GLOBAL TECHNOLOGY OPERATIONS, INC., DETROIT, MI (US)

(21) Appl. No.: 11/872,075

(22) Filed: Oct. 15, 2007

(51) Int. Cl. H04M 1/02; G08G 1/123; H04Q 7/00; H05K 11/00

(52) U.S. Cl. 455/556.1; 340/539.13; 340/990; 455/344

(57) ABSTRACT

A portable cellular communication device and system is provided for finding the current location of a vehicle on demand by a user. The portable cellular communication device can direct the user to a parked vehicle utilizing location data of the portable cellular communication device provided by a GPS transmitter or a wireless node, and current vehicle location information provided by accessing a vehicle location database.

### TECHNICAL FIELD

Embodiments of the present invention relate generally to an apparatus and method for locating a vehicle and, more particularly, to a wireless communication device and method for providing location information to a cell phone.

### BACKGROUND

Nearly everyone, at one time or another, has experienced difficulty in locating a parked vehicle. Malls, airports, and other large venues often feature parking garages or tiered parking structures that make losing a vehicle particularly easy and finding a parked vehicle particularly challenging. Portable short-range wireless communication devices have been developed that may help a driver locate a parked vehicle. Once the vehicle is parked, these devices may detect and store the vehicle location information while they are in the vicinity of the parked vehicle so that the driver can find the vehicle using the stored vehicle location information if needed. However, if the vehicle is moved (e.g., by a valet, if it is stolen, if it is towed) the stored vehicle location information no longer represents the current location of the vehicle.

Thus, it is desirable to have remote access to the current vehicle location information on demand by the user via a long-range wireless communication device. Moreover it is desirable to have remote access to parked vehicle location information where satellite reception is poor or lacking. Other desirable features and characteristics of the present invention will become apparent from the subsequent detailed description and the appended claims, taken in conjunction with the accompanying drawings and the foregoing technical field and background.

### BRIEF SUMMARY

A portable cellular communication device is configured for directing a user to a vehicle. The device utilizes its location information, which can be provided by at least one local wireless node or a GPS satellite transmitter, and current vehicle location information provided by a remote database. An embodiment of the device includes the following: a network receiver configured to receive device location data that indicates a current location of the portable cellular communication device; a cellular transceiver configured to transmit an activation signal via a cellular network, the activation signal representing a request from the user to locate the vehicle, and the cellular transceiver being configured receive, via the cellular network and in response to the activation signal, vehicle location data that indicates a current location of the vehicle; and a controller coupled to the network receiver and the cellular transceiver, the controller being configured to determine, from the device location data and the vehicle location data, a position of the vehicle relative to the portable cellular communication device.

A cellular communication system for directing a user to a vehicle is also provided. An embodiment of the cellular communication system includes: a vehicle location database configured to store vehicle location data that indicates a current location of the vehicle; a remote transceiver coupled to the vehicle location database and configured to provide remote user access to the vehicle location data; and a portable cellular communication device. In certain embodiments the portable cellular communication device includes: a device transceiver configured to transmit an activation signal to the remote transceiver at the demand of a user, and configured to receive the vehicle location data from the remote transceiver in response to the activation signal; a network receiver configured to receive device location data that indicates a current location of the portable cellular communication device; a controller coupled to the network receiver and to the device transceiver, the controller being configured to determine, from the device location data and the vehicle location data, a position of the vehicle relative to the portable cellular communication device; and a vehicle position indicator coupled to the controller and configured to generate indicia of the position of the vehicle relative to the portable cellular communication device.

A method is provided for guiding a user to a vehicle using a portable cellular communication device carried by the user. The method begins by processing an on-demand request from the user to locate the vehicle. In response to the on-demand request, the method wirelessly interrogates a remote database to obtain vehicle location data that indicates a current location of the vehicle. The method then determines the current location of the portable cellular communication device, determines, from the device location data and the vehicle location data, a position of the vehicle relative to the portable cellular communication device, and generates indicia of the position of the vehicle relative to the portable cellular communication device.

### BRIEF DESCRIPTION OF THE DRAWINGS

Embodiments of the present invention will hereinafter be described in conjunction with the following drawing figures, wherein like numerals denote like elements, and

FIG. 1 is a plan view of a cell phone having a vehicle location function in accordance with a first exemplary embodiment;

FIG. 2 illustrates a find vehicle control element for the cell phone shown in FIG. 1;

FIG. 3 is a front plan view of a cell phone having a vehicle location function in accordance with a second exemplary embodiment;

FIG. 4 illustrates a find vehicle control element for the cell phone shown in FIG. 3;

FIG. 5 is a block diagram showing a vehicle location system that may be incorporated into a portable cellular communication device, such as the cell phone shown in FIG. 1, or the cell phone shown in FIG. 3, and a remote transceiver in communication with such cell phones;

FIG. 6 is a map of a shopping mall and parking area including a plurality of nodes illustrating a scenario involving a user that requires assistance to return to a parked vehicle;

FIG. 7 is a flowchart illustrating an exemplary process utilized by the vehicle location system shown in FIG. 5 to guide the user shown in FIG. 6 back to the parked vehicle; and

FIG. 8 is a diagram illustrating one manner in which audible signals produced by the vehicle location system shown in FIG. 5 may be altered in relation to the heading of the system relative to the location of the vehicle.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

Embodiments of the invention may be described herein in terms of functional and/or logical block components and various processing steps. It should be appreciated that such block components may be realized by any number of hardware, software, and/or firmware components configured to perform the specified functions. For example, an embodiment of the invention may employ various integrated circuit components, e.g., memory elements, controlled switches, digital signal processing elements, logic elements, look-up tables, or the like, which may carry out a variety of functions under the control of one or more microprocessors or other control devices. In addition, those skilled in the art will appreciate that embodiments of the present invention may be practiced in conjunction with any number of vehicle applications and that the system described herein is merely one example embodiment of the invention.

For the sake of brevity, conventional techniques and components related to vehicle components, cellular telephony, GPS and other location systems and other functional aspects of the system (and the individual operating components of the system) may not be described in detail herein. Furthermore, the connecting lines shown in the various figures contained herein are intended to represent example functional relationships and/or physical couplings between the various elements. It should be noted that many alternative or additional functional relationships or physical connections may be present in an embodiment of the invention.

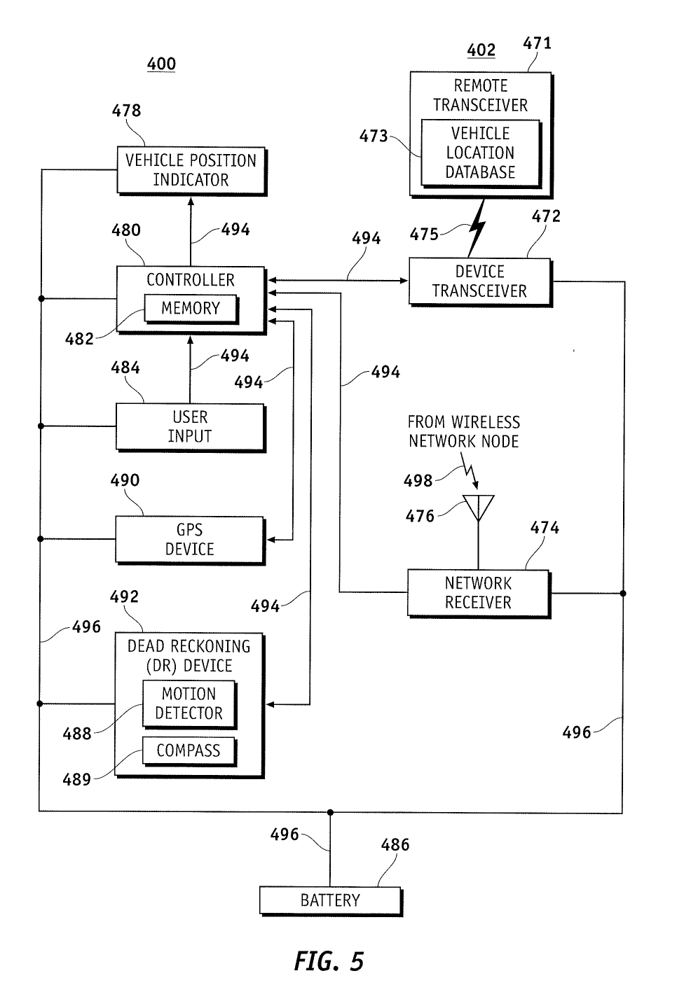

The following description may refer to elements or nodes or features being “connected” or “coupled” together. As used herein, unless expressly stated otherwise, “connected” means that one element/node/feature is directly joined to (or directly communicates with) another element/node/feature, and not necessarily mechanically. Likewise, unless expressly stated otherwise, “coupled” means that one element/node/feature is directly or indirectly joined to (or directly or indirectly communicates with) another element/node/feature, and not necessarily mechanically. Thus, although the block diagram shown in FIG. 5 depicts a typical arrangement of elements, additional intervening elements, devices, features, or components may be present in an embodiment of the invention (assuming that the functionality of the system is not adversely affected).

Embodiments of the invention are described herein in the context of one practical non-limiting application, namely, a system for providing location information for a parked car. Embodiments of the invention, however, are not limited to such vehicle applications, and the techniques described herein may also be utilized to provide location information between any two relative points of interest.

Embodiments of the devices and systems described herein access vehicle location information on demand by a user via a long range wireless network, such as a cellular telecommunication network. Thus, the techniques described here are suitable for use with a portable cellular communication device (such as a cellular telephone, a cellular enabled personal digital assistant, a cellular enabled computing device, etc.), which can be used to find the current location of a vehicle and guide the user back to his vehicle. Notably, the current vehicle location data is made available for access through the cellular network.

Telematics-based systems may be configured to dial a vehicle and determine the vehicle's location using suitable location determination techniques. Alternatively, location information could be left in an onboard vehicle system, but be accessible using a cell phone call to the vehicle. For example, a customer attempting to locate the vehicle could call the vehicle using a cellular device and retrieve vehicle location information. This information could then be used with a GPS-enabled device to facilitate a “guide to vehicle” function. Furthermore, the information could be acquired by the phone and then passed from the phone to another device. This data transfer could be via a Bluetooth link or other wired or wireless link, and allow a separate device, such as a GPS device, or a PDA, to assist in the vehicle locating activity.

Although the embodiments described herein relate to a cell phone deployment, the associated techniques and technologies can be utilized with any portable wireless device, including, but not limited to, a PDA device, a pager device, a handheld video game device, a key fob device, a mobile phone, a digital watch, or a digital audio file player (e.g., an MP3 or MP4 player).

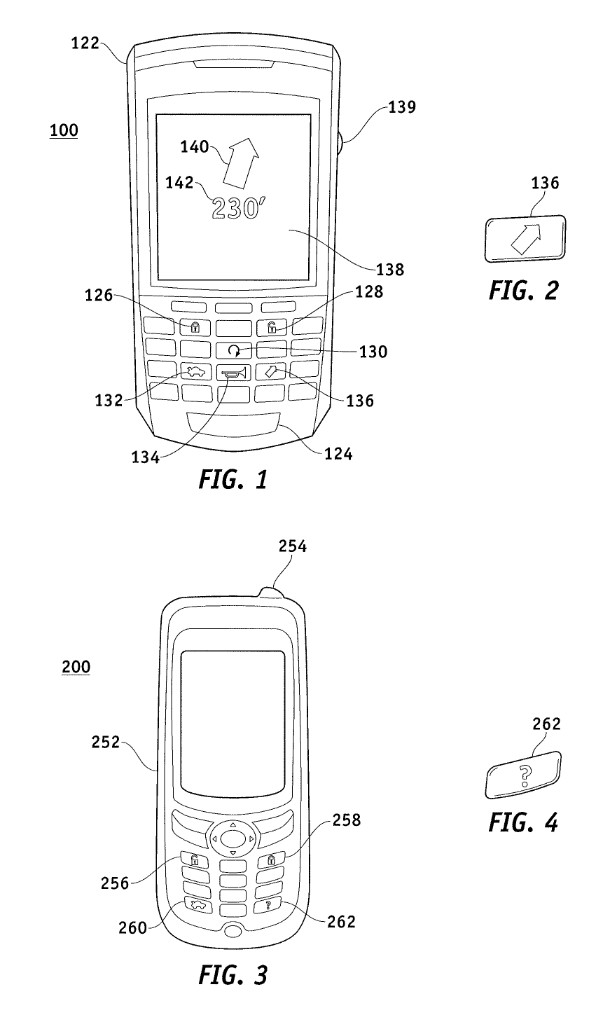

FIG. 1 is a plan view of a cell phone 100 having a parked vehicle location function in accordance with a first exemplary embodiment of the present invention. Cell phone 100 comprises a housing 122 that provides a structural foundation for its electronics and hardware. A plurality of control elements or functions may be provided in a variety of forms such as: a GUI-based soft key, a button or other element on the exterior of housing 122, a sequence of numbers or other buttons that can be entered by the user, a voice command, a touch screen input, or other user interface. The plurality of control elements may include, for example, a lock control element 126, an unlock control element 128, a feature scroll control element 130, a trunk unlock control element 132, a panic control element 134, and a find vehicle control element 136 (also shown in FIG. 2).

Cell phone 100 further comprises a display (e.g., a liquid crystal display) 138 that may display status information relating to a vehicle associated with cell phone 100. This status information may include the vehicle's mileage, tire pressure, current fuel level, radio station settings, and door lock status. In particular, the user may need to navigate through the menu of the phone to get to an appropriate screen so that he can then select the find vehicle function. For example, a feature scroll control element 130 may be utilized to navigate through the data. For example, pressing feature scroll control element 130 once may cause the vehicle's mileage to appear on display 138, pressing feature scroll control element 130 twice may cause the find vehicle function to appear on display 138, and so forth. The user may then select and activate the find vehicle function.

When a user activates the find vehicle control element 136, cell phone 100 provides visual prompts on display 138 that may guide the user back to his or her parked vehicle in the manner described below. For example, as indicated in FIG. 1, an arrow 140 may be generated on display 138 indicating the position of the vehicle relative to the heading of cell phone 100. In addition, an estimated phone-to-car distance may also be displayed on display 138 as shown at reference number 142. This example notwithstanding, it should be appreciated that other embodiments of cell phone 100 may utilize other visual indications to guide a user back to the vehicle, such as a simple map, a three-dimensional rendering of a desired route, or the like. In still other embodiments, cell phone 100 may produce audible signals in addition to, or in lieu of, visual signals.

FIG. 3 is a plan view of a specialized cell phone 200 in accordance with a second embodiment of the present invention. Cell phone 200 comprises a housing 252 which includes a stem portion 254. A plurality of control elements are disposed on housing 252 and may include an unlock control element 256, a lock control element 258, a trunk open control element 260, and a find vehicle control element 262 (also shown in FIG. 4).

Stem portion 254 may be received by a receptacle (e.g., a socket) provided within the passenger compartment of a vehicle. Such a receptacle may be configured to supply power to cell phone 200 and, possibly, to recharge a battery disposed within housing 252. For example, the receptacle may employ a conventional electromagnetic induction system comprising an oscillator circuit and a first coil. The oscillator circuit may intermittently activate the first coil to generate a time-varying magnetic field proximate the receptacle. A second coil (not shown) may be disposed within stem portion 254 and coupled to a microcontroller contained within housing 252. When stem portion 254 is inserted into the receptacle, a voltage is induced in the second coil, which cell phone 200 may use as an energy source to power its microcontroller and/or to recharge its battery.

As was the case with cell phone 100, cell phone 200 is configured such that find vehicle control element 262 may be utilized to activate a vehicle location function incorporated into cell phone 200. However, unlike cell phone 100, cell phone 200 utilizes a sound generator disposed within housing 252 to provide audio cues (e.g., a series of beeps) indicative of the position of the vehicle relative to cell phone 200 as described in more detail below.

Cell phone 100 (FIG. 1) and cell phone 200 (FIG. 3) preferably communicate with their respective vehicles via radio frequency signals using the CDMA, GSM, and/or similar wireless cellular communication standards; however, it should be appreciated that other wireless communication techniques and protocols may be utilized as well, including, but not limited to, an induction-based means, a low frequency (e.g., 30-300 kHz) communication means, or an infrared means. Furthermore, other embodiments may comprise a cell phone that communicates with a vehicle over a hard wire connection for purposes unrelated to vehicle locating, e.g., a cell phone having a mechanical blade fixedly coupled thereto that carries an electrical connector (e.g., a D-subminiature connector, a multi-pin USB connector similar to that employed by a portable flash drive device, etc.) that permits electrical communication with the vehicle when the blade is inserted into the vehicle's ignition.

FIG. 5 is a block diagram that depicts a parked vehicle location system 400 that may be incorporated into a portable cellular communication device. Location system 400 is preferably incorporated into a cell phone, such as cell phone 100 shown in FIG. 1 or cell phone 200 shown in FIG. 3. System 400 is configured to communicate with a remote transceiver 471 to access and obtain current vehicle location data as described herein.

Location system 400 comprises: a device transceiver 472, a network receiver 474 including an antenna 476, a parked vehicle position indicator 478, a controller 480 (e.g., a microcontroller) including a memory 482, a user input 484 (e.g., a control element, a GUI-based soft key, a voice-activated instruction, a touchscreen icon, a displayed feature that can be selected with a user pointing element such as a touchpad or a joystick, or the like), and a battery 486. In the illustrated embodiment, location system 400 also comprises a global positioning (GPS) device 490 and a dead reckoning (DR) device 492 including a motion detector 488 and an electronic compass 489; however, other embodiments of the present invention may not include one or more of these components. A plurality of communication lines 494 operatively couple controller 480 to the other components of location system 400. For example, controller 480 may receive electrical signals from device transceiver 472, network receiver 474, user input 484, GPS device 490, and DR device 492 (and thus from motion detector 488 and electronic compass 489); and controller 480 may send electrical signals to position indicator 478 and GPS device 490. Battery 486 supplies power to each of the components of location system 400 via connections 496.

Position indicator 478 may comprise any indication means suitable for providing a user with information useful in locating a parked vehicle. Position indicator 478 may be, for example, a sound generator or a visual signal generator (e.g., a display, such as display 138 shown in FIG. 1). Similarly, device transceiver 472 may comprise any device suitable for receiving data originating from a remote vehicle location database 473, where such vehicle location data indicates the vehicle's current location (referred to herein as current vehicle location information). For example, device transceiver 472 may comprise a wireless transceiver, such as an RF transceiver that is configured in accordance with common compatibility standards for cellular (e.g., CDMA, GSM standards), wireless local area networks (e.g., Wi-Fi standards), or for personal area networks (e.g., Bluetooth standards). In certain embodiments, the device transceiver 472 may additionally or alternatively be configured to receive current vehicle location data indirectly from an intermediary device, system, or component that serves as a repeater or relay for the remote transceiver 471. In preferred embodiments, device transceiver 472 is realized as (or includes) a cellular radio of the type commonly used in cellular telephones.

As shown in FIG. 5, the device transceiver 472 communicates with remote transceiver 471 (system 402) via a communication link 475. In practice, communication link 475 is established using a cellular network, and communication link 475 may have any number of wireless and wireless components (i.e., sublinks). The device transceiver 472 is configured to establish communication with, and receive a signal from, the remote transceiver 471, where the received signal conveys the current vehicle location information in response to an on-demand user request as described herein. The remote transceiver 471 includes a vehicle location database 473 that stores the current vehicle location data. The remote transceiver 471 may be configured in accordance with common compatibility standards for cellular (e.g., CDMA, GSM standards), wireless local area networks (e.g., Wi-Fi standards), or for personal area networks (e.g., Bluetooth standards). Depending upon the particular deployment, the remote transceiver 471 may be part of an onboard vehicle system of the vehicle of interest, or it may be located in a location that is remote from the vehicle, e.g., at a central server facility, at a telematics service provider facility, etc.

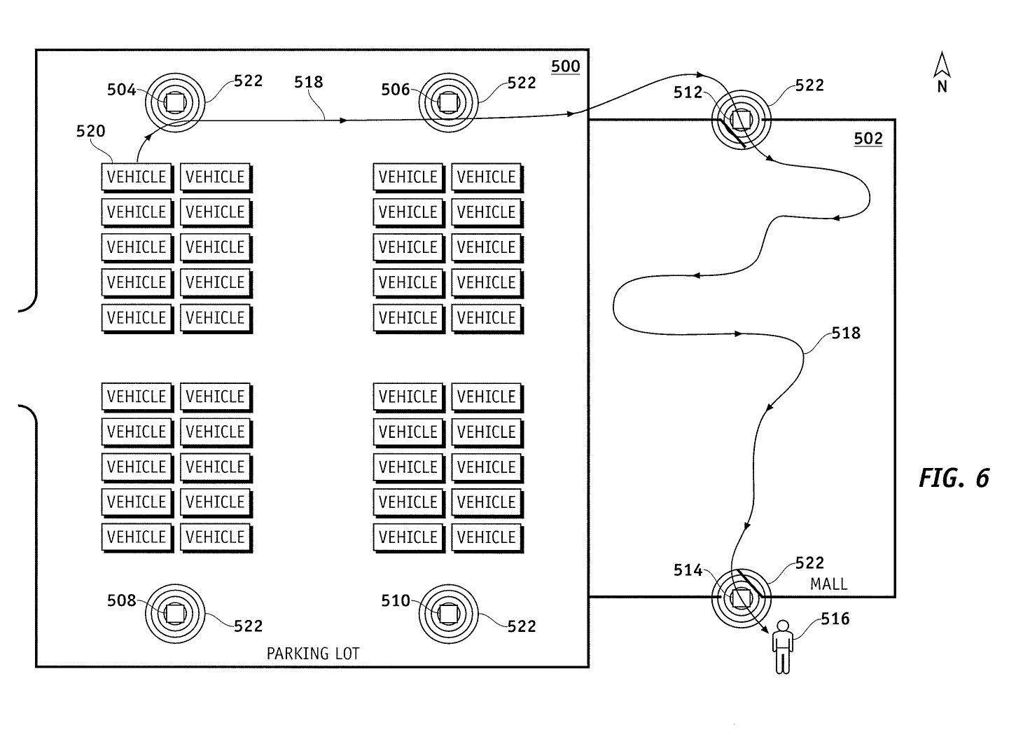

Network receiver 474 is configured to receive signals broadcast by nearby wireless network nodes (indicated in FIG. 5 at 498), and to provide related signals to controller 480. Exemplary wireless network nodes, and their operation in the context of vehicle location, are described in more detail below with reference to FIG. 6. To this end, controller 480 and network receiver 474 may be configured in accordance with common compatibility standards for cellular (e.g., CDMA, GSM standards), wireless local area networks (e.g., Wi-Fi standards), or for personal area networks (e.g., Bluetooth standards). In certain exemplary embodiments, controller 480 and network receiver 474 may be configured in accordance with low data transmission rate networks (e.g., IEEE 802.n, 802.15.4, 802.11a-g, Zigbee). Such low data rate standards have a data transmission rate slower than that of Wi-Fi or Bluetooth standards (e.g., 250 Kbps at 2.4 GHz), but consume relatively little power and thus may help prolong the life of battery 486. For this reason, adapting controller 480 and network receiver 474 to operate at low data transmission rate standards may be especially desirable in embodiments wherein battery 486 is not readily capable of being recharged.

As indicated above, location system 400 may be provided with a motion detector 488, which may be incorporated into a dead reckoning device, such as DR device 492. Motion detector 488 may comprise any movement-sensitive device. For example, motion detector 488 may comprise a circular spring mounted concentric to a pin or wire that passes freely through the center of the circular spring. When motion detector 488 experiences any significant amount of motion, the spring deflects and touches the pin or wire to complete an electrical circuit. When the motion stops, the surrounding spring returns to its quiescent state wherein the pin or wire is not contacted. Such a motion detectors are well-known in the art and desirable for use in conjunction with location system 400 due to their modest power requirements.

To measure traveled distance, DR device 492 may utilize motion detector 488 as a pedometer; that is, DR device 492 may utilize motion detector to measure the number of steps taken by a user. To estimate the direction traveled, DR device 492 may further employ a compass, such as electronic compass 489. Utilizing information provided from DR device 492 relating to distance and direction of movement, controller 480 may estimate the location of location system 400 relative to a known reference point in the well-known manner. DR devices suitable for use as DR device 492 are known and commercially available.

In certain embodiments, vehicle location system 400 may include a conventional GPS device 490. When able to receive satellite signals of sufficient quality, GPS device 490 may be utilized to determine the location of location system 400 and, thus, the location of the host portable wireless communication device (e.g., a cell phone). However, in the absence of GPS data, location system 400 may determine its location by reference to node location data provided by one or more wireless network nodes as explained in more detail below.

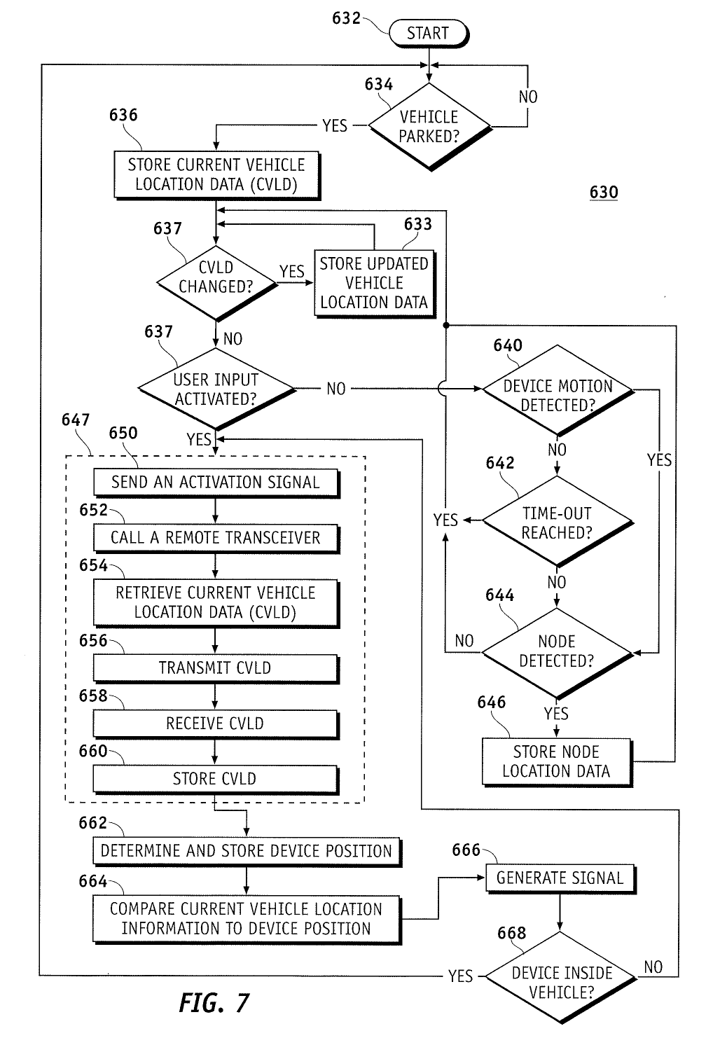

FIG. 6 illustrates a network of local wireless nodes disposed at various locations in a parking area (e.g., a parking garage) 500 and a neighboring shopping mall 502. Six such nodes are shown: nodes 504, 506, 508, 510, 512, and 514. Nodes 504, 506, 508, and 510 are each disposed in a different quadrant of parking area 500, and nodes 512 and 514 are disposed at the North and South entrances, respectively, of shopping mall 502. Although transmission range 522 for each of the wireless nodes is shown in FIG. 6 as being relatively limited for clarity, wireless nodes 504, 506, 508, 510, 512, and 514 may each transmit a signal detectable over relatively large range (e.g., a low-power Zigbee network node may have a transmission range of approximately 50 meters). The following description will refer to FIG. 6 in conjunction with FIGS. 5 and 7 in describing an exemplary manner in which location system 400 (FIG. 5) may guide a user 516 back to a parked vehicle 520 after the user has walked a path 518.

FIG. 7 is a flowchart illustrating a process 630 that may be performed by location system 400 and remote transceiver system 402 to guide user 516 back to parked vehicle 520. To begin (task 632), remote transceiver 471 first determines if vehicle 520 has been parked (task 634). As will be appreciated, the remote transceiver 471 may determine this in a number of different manners through status, navigation, or position data received via a cell network, a telematics system, or a GPS system. A determination of vehicle park status can be made by the vehicle, for example, by monitoring its park, reverse, neutral, drive, low (PRNDL) gear switch, by determining when its ignition has been turned off, or by determining when the driver's side door has been opened and subsequently locked. After establishing that vehicle 520 has been parked, the remote transceiver 471 stores the current vehicle location data in the vehicle location database 473 (the remote database that is coupled to the remote transceiver 471). Notably, this current vehicle location data is indicative of the vehicle's current parked location (task 636). This current vehicle location information may comprise, for example, GPS coordinates that are provided by a GPS system onboard vehicle 520.

After storing information relating to the current vehicle location (task 636) in vehicle location database 473 of the remote transceiver 471, the current vehicle location data may be accessed remotely by the cell phone in response to a user input (on demand by the user). The technique described here is particularly beneficial because it does not assume that the vehicle will remain stationary. In this regard, process 630 may continuously or periodically receive vehicle location data for purposes of monitoring the ongoing position of the vehicle. If the location of the vehicle has changed (query task 637), then the vehicle location database 473 stores the updated vehicle location data, which is associated with the new location of the vehicle (task 633). After storing the new vehicle location data, process 630 can be re-entered at query task 637 to continue monitoring for additional changes in the vehicle position.

Concurrently with updating the vehicle location data, process 630 checks for an on-demand “locate vehicle” request from the user. In this regard, process 630 may handle an on-demand request from the user to locate the vehicle. For this embodiment, controller 480 determines if user input 484 has been activated, e.g., if the find vehicle control element 136 (FIGS. 1-2) or control element 262 (FIG. 3-4) has been activated (task 638). If it is determined that user input 484 has not been activated, controller 480 determines if motion is detected by motion detector 488 contained in the cellular device (task 640). In this regard, process 630 assumes that any detected motion corresponds to movement (e.g., walking) of the user. If motion is detected, controller 480 establishes whether a wireless node is currently detected by the network receiver 474 of the cellular device (task 644) as described below. If motion is not detected, controller 480 determines whether a time-out has been reached (task 642). Controller 480 makes this determination by reference to a predetermined time period (e.g., two minutes). If controller 480 determines that motion has not been detected for the pre-determined time period, process 630 is re-entered at query task 637 to continue monitoring for a change in the vehicle position and to continue monitoring for activation of user input 484 (task 638).

After determining that motion has been detected (task 640) or that a time-out has not been reached (task 642), controller 480 next establishes whether a location-specific wireless node signal is currently detected by the network receiver 474 of the cellular device (task 644). This type of node signal is utilized to convey the physical location coordinates of the transmitting node. If such a signal is not detected, controller 480 returns to task 637. However, if such a signal is detected, the node location data provided by the transmitting node is stored in memory 482 (task 646) and controller 480 returns to (task 637). If multiple location-specific signals are detected, controller 480 may identify which signal is broadcast by the nearest node by, for example, comparing signal strength. Thus, by repeating tasks 640, 642, 644, and 646, controller 480 may continually update the approximate location of the portable wireless communication device carrying system 400 by reference to the location of the nodes passed while user 516 walks along path 518. Note that this activity occurs in the background even though the user has not requested any guidance to his or her vehicle.

Upon activation of the user input 484, the device transceiver 472 accesses the current vehicle location data by wirelessly interrogating the vehicle location database. This may be performed by initiating a call via a cellular network so that the current vehicle location data can be retrieved during the call. Accessing the current vehicle location information may be accomplished by the following steps: sending an activation signal from the controller 480 to the device transceiver 471 in response to user interaction with the user-selectable find vehicle control element 136/262 (task 650); thereafter wirelessly (using the cellular network) sending a request signal (calling) the remote transceiver 471 (task 652); and wirelessly retrieving the current vehicle location data from the vehicle location database 473 (task 654). Next, the remote transceiver 471 wirelessly transmits the current vehicle location data to the device transceiver 472, preferably during the same cellular call (task 656), and the device transceiver 472 wirelessly receives the current vehicle location data from the remote transceiver 471 (task 658). Then, the process 630 stores the current vehicle location data in the controller memory 482 (task 660) for the subsequent processing described herein.

Controller 480 then estimates the location of the cellular device carrying vehicle location system 400 (task 662). This may be accomplished by utilizing GPS device 490 as described above. However, in accordance with an exemplary embodiment of the present invention, this may also be accomplished by referring to the node location data stored in memory 482 previously provided by the local wireless nodes encountered along path 518. Controller 480 may determine the location of location system 400 by simply recalling the data associated with the last location-specific signal received, assuming that the location of system 400 is substantially equivalent to the position of that particular node (e.g., node 514). However, for increased accuracy, controller 480 may instead utilize the data associated with the last location-specific signal as a reference point and extrapolate the current location of system 400 utilizing direction and distance information provided by DR device 492.

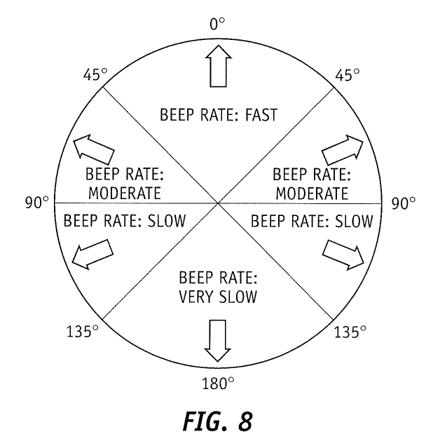

Eventually, the location of the cell phone device is then compared to the current vehicle location data (task 664) to determine the position of vehicle 520 relative to the carried device. In addition, controller 480 generates a signal indicative of the position of vehicle 520 relative to the device via position indicator 478 (task 666). As explained above, this signal may comprise audible and/or visual cues. The generated signal may be indicative of the distance between location system 400 and vehicle 520 (e.g., a graphical indication of the distance between system 400 and vehicle may be generated as shown in FIG. 1 at 142, or a series of beeps may be produced wherein the frequency of the beeps increases as the distance between the device and vehicle 520 decreases). In addition, or alternatively, the generated signal may be indicative of the direction of vehicle 520 relative to the device. In this case, a visual signal may take the form of an arrow and an audible signal may take the form of a series of beeps that varies in frequency in relation to a location of vehicle 520 relative to the heading of the device carrying system 400. For example, as illustrated in FIG. 8, system 400 may produce a constant beep when the device is headed towards (pointed at) the location of vehicle 520 (0 degrees) or offset from this heading by 45 degrees in either the clockwise or counter-clockwise direction. If the heading of the device is offset from the direction of the vehicle 520 by 45-90 degrees, a fast beep rate may be produced. If the heading of the device is offset from the direction of the vehicle by 90-135 degrees, a moderate beep rate may be generated. Finally, if the heading of the device is offset from the direction of the vehicle by 135-180 degrees, a slow beep rate may be produced. These generated signals may thus guide user 516 back to parked vehicle 520.

After generating a signal indicative of the position of parked vehicle 520, controller 480 determines whether the device carrying location system 400 is within vehicle 520 (task 668) and, therefore, no longer needed to assist user 516 back to vehicle 520. If the device has not yet been placed inside the vehicle, process 630 can be re-entered at, for example, task 650 to repeat the procedure described above, resulting in further direction guidance to user 516. However, after the device has been placed inside vehicle 520 and user 516 no longer requires direction guidance, process 630 may end or return to task 634 to wait until the vehicle is parked again.

For ease of description, FIG. 7 depicts tasks 640, 642, 644, and 646 as being distinct from the remainder of the flow chart. In practical embodiments, however, these tasks may continue to be performed in the background concurrently with other tasks of process 630 to continually update the node location data stored in memory 482.

In view of the above, it should be appreciated that a parked vehicle location system has been provided for finding the current location of a vehicle on demand by a user and that may be employed in a cellular communication device (e.g., a cell phone) configured to be carried on the user's person.

Although described above as utilizing location-specific signals provided by wireless nodes to determine the location of system 400, it should be understood that controller 480 may also employ other radiolocation means in determining the location of system 400 including assisted GPS and enhanced 911 (E911). It should also be understood that, in certain embodiments, system 400 may determine the current location of the parked vehicle by wirelessly querying the vehicle after activation of the vehicle location function in the well-known manner.

While at least one embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any manner. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

What is claimed is:

1. A portable cellular communication device for directing a user to a vehicle, the portable cellular communication device comprising:
a network receiver configured to receive device location data that indicates a current location of the portable cellular communication device;
a cellular transceiver configured to transmit an activation signal via a cellular network, the activation signal representing a request from the user to locate the vehicle, and the cellular transceiver being configured to receive, via the cellular network and in response to the activation signal, vehicle location data that indicates a current location of the vehicle; and
a controller coupled to the network receiver and the cellular transceiver, the controller being configured to determine, from the device location data and the vehicle location data, a position of the vehicle relative to the portable cellular communication device.

2. The portable cellular communication device according to claim 1, wherein the network receiver is further configured to receive wireless node location data from at least one local wireless node to obtain received node location data to estimate the location of the portable cellular communication device from the received node location data.

3. The portable cellular communication device according to claim 1, further comprising a vehicle position indicator coupled to the controller and configured to generate at least one signal indicative of the position of the vehicle relative to the portable cellular communication device.

4. The portable cellular communication device according to claim 3, wherein the vehicle position indicator comprises a display.

5. The portable cellular communication device according to claim 3, wherein the vehicle position indicator comprises a sound generator.

6. The portable cellular communication device according to claim 1, wherein the cellular transceiver transmits the activation signal in an outgoing call initiated by the user.

7. The portable cellular communication device according to claim 1, wherein the cellular transceiver receives the vehicle location data from a communication system that is onboard the vehicle.

8. The portable cellular communication device according to claim 7, wherein the communication system comprises a vehicle location database configured to store the vehicle location data.

9. The portable cellular communication device according to claim 1, wherein the cellular transceiver receives the vehicle location data from a communication system that is remote from the vehicle.

10. A cellular communication system for directing a user to a vehicle, the cellular communication system comprising:
a vehicle location database configured to store vehicle location data that indicates a current location of the vehicle;
a remote transceiver coupled to the vehicle location database and configured to provide remote user access to the vehicle location data; and
a portable cellular communication device comprising:
a device transceiver configured to transmit an activation signal to the remote transceiver at the demand of a user, and configured to receive the vehicle location data from the remote transceiver in response to the activation signal;
a network receiver configured to receive device location data that indicates a current location of the portable cellular communication device;
a controller coupled to the network receiver and to the device transceiver, the controller being configured to determine, from the device location data and the vehicle location data, a position of the vehicle relative to the portable cellular communication device; and
a vehicle position indicator coupled to the controller and configured to generate indicia of the position of the vehicle relative to the portable cellular communication device.

11. The system according to claim 10, the portable cellular communication device further comprising:
a housing containing the device transceiver, the network receiver, and the controller;
a display element coupled to the housing, the display element being configured to display a user-selectable Find Vehicle control element; and
wherein the vehicle position indicator is configured to generate the indicia of the position of the vehicle relative to the portable cellular communication device when the user-selectable Find Vehicle control element is activated.

12. The system according to claim 10, wherein the remote transceiver is further configured to:
receive the activation signal from the device transceiver via a cellular network, the activation signal representing a request to retrieve the vehicle location data from the vehicle location database; and
send the vehicle location data to the device transceiver via the cellular network.

13. The system according to claim 10, the portable cellular communication device further comprising a dead reckoning device coupled to the controller.

14. The system according to claim 13, wherein the dead reckoning device includes:
a motion detector; and
an electronic compass.

15. A method for guiding a user to a vehicle using a portable cellular communication device carried by the user, the method comprising:
processing an on-demand request from the user to locate the vehicle;
in response to the on-demand request, wirelessly interrogating a remote database to obtain vehicle location data that indicates a current location of the vehicle;
determining a current location of the portable cellular communication device;
determining, from the device location data and the vehicle location data, a position of the vehicle relative to the portable cellular communication device; and
generating indicia of the position of the vehicle relative to the portable cellular communication device.

16. The method according to claim 15, wherein determining the current location of the portable cellular communication device comprises:
receiving wireless node location data from at least one local wireless node to obtain received node location data; and
storing the wireless node location data to estimate the current location of the portable cellular communication device from the received node location data.

17. The method according to claim 15, wherein generating the indicia comprises generating a position signal corresponding to the vehicle.

18. The method according to claim 17, further comprising altering the position signal in relation to a heading of the portable cellular communication device relative to the position of the vehicle.

19. The method according to claim 17, further comprising altering the position signal in relation to a distance between the vehicle and the portable cellular communication device.

20. The method according to claim 15, wherein:
wirelessly interrogating the remote database comprises initiating a call via a cellular network; and
the portable cellular communication device receives the vehicle location data during the call and via the cellular network.
